(19) United States
(12) Patent Application Publication
(10) Pub. No.: US 2004/0208274 A1
(43) Pub. Date: Oct. 21, 2004

(54) Method for guaranteeing stable non-linear PLLs

(76) Inventor: Daniel Y. Abramovitch, Palo Alto, CA (US)

Correspondence Address: AGILENT TECHNOLOGIES, INC., Legal Department, DL429, Intellectual Property Administration, P.O. Box 7599, Loveland, CO, 80537-0599, US

(21) Appl. No.: 10/414,791

(22) Filed: Apr. 16, 2003

(51) Int. Cl. H03D 3/24; H03L 7/08

(52) U.S. Cl. 375/376; 327/156

(57) ABSTRACT

A design methodology for an Alexander-type PLL may begin by defining a candidate Lyapunov function that is parameterized by design parameters of the Alexander-type PLL. Then, a set of design constraints may be derived from said candidate Lyapunov function and a first derivative of said candidate Lyapunov function. From the design constraints, values for the design parameters of an Alexander-type PLL may be selected. Specifically, when the phase detector gain, the VCO gain, the filter coefficients, and/or the like are selected to satisfy the derived design constraints, the implemented Alexander-type PLL is ensured to be stable.

### BACKGROUND OF THE INVENTION

Phase lock loops (PLLs) are well known devices that lock the phase of a generated signal to the phase of a reference signal. It is frequently advantageous to implement a PLL utilizing digital circuitry to perform phase detection. For example, clock signals to drive digital circuitry, computers, and digital communication systems exhibit improved performance when driven by Walsh functions (rectangular waves) as opposed to sinusoids. Several digital phase detectors for use in digital PLLs are advantageous for detecting the phase of the underlying clock signal in non-return-to-zero (NRZ) digital data. Digital circuitry is typically easier to integrate and verify than analog counterparts. Moreover, as the speed of the logic of the digital circuitry outstrips the requirements of a given application, the reliability of digital PLLs is appreciably improved relative to classical analog designs.

In operation, a reference signal may be received by digital phase detector. The digital phase detector generates a phase signal that is indicative of the phase difference between the reference signal and a generated signal. Depending upon the implementation of the digital phase detector, the phase signal may simply indicate whether the generated signal is “early” or “late” relative to the reference signal. Alternatively, the phase signal may provide some amount of information indicative of the amount of delay between the signals. The phase signal may be filtered by a loop filter. The filtered signal drives a voltage controlled oscillator (VCO) to produce the generated signal. By providing feedback in this manner, the generated signal is phase-locked to the reference signal.

When analyzing a digital PLL, it is assumed that the high frequency portion of the phase detector response is attenuated by any low pass filter in the loop and by the low-pass nature of the PLL itself. Moreover, it is assumed that the VCO frequency (ωₒ) is sufficiently close to the underlying clock frequency of the reference signal (ωᵢ) that their difference can be incorporated into θₑ. This assumption means that the VCO may be modeled as an integrator.

FIG. 1 depicts the mathematical model 100 (often called the baseband or modulation domain model) based on these assumptions. In mathematical model 100, θᵢ represents the phase of the reference signal, θₑ represents the phase error signal, and θₒ represents the phase of the generated signal. K_{d} represents the gain of the phase detector and f_{D}( ) represents the non-linear characteristic of the phase detector. F(s) represents the transfer function of the loop filter. The VCO is modeled as an integrator and, hence, Kₒ/s represents the transfer function of an integrator with gain Kₒ.

When implementing a PLL, the selection of loop parameters (i.e., the phase detector gain, the VCO gain, and the filter coefficients) is made to attempt to ensure that the loop is stable. Instability of the loop may have significant consequences. For example, an unstable PLL in a microelectronic system would result in the PLL being unable to lock to the reference signal thereby rendering the system inoperable. Accordingly, demonstrating stability is requisite for most practical applications of PLLs.

Furthermore, a number of implementations of digital phase detector 102 cause digital phase detector 102 to be linear within a limited range of operation. In such implementations, the non-linear characteristic (f_{D}( )) of digital phase detector 102 is ignored over that limited range. By ignoring the non-linear characteristic, classical continuous time linear feedback analysis may be performed. Such classical analysis may be utilized to determine whether a particular design will be stable by demonstrating that the system transfer function is stable.

However, it is not always possible to base stability analysis on a limited range of linear operation. For example, the Alexander phase detector does not possess a linear region of baseband operation. Specifically, an Alexander phase detector generates a uniform high signal whenever the generated signal is late relative to the reference signal and a uniform low signal whenever the generated signal is early relative to the reference signal. Alexander phase detectors are commonly referred to as “bang-bang” phase detectors due to the response characteristic. Because the baseband operation is never linear, classical linear filter analysis cannot be applied. Thus, existing methodologies do not provide a ready mechanism to demonstrate that a contemplated design of an Alexander-type PLL will be stable. Instead, mere general rules of thumb have been provided which facilitate (but do not guarantee) implementation of a stable Alexander-type PLL.

### BRIEF SUMMARY OF THE INVENTION

Embodiments in accordance with the invention provide a design methodology that ensures a stable implementation of a PLL that utilizes an Alexander phase detector (hereinafter referred to as an Alexander-type PLL). The design methodology has been enabled, because it has been determined that the baseband behavior of an Alexander phase detector exhibits [0,∞] sector non-linearity for −π<θₑ<π. Specifically, a function, f(t,y), is said to belong to sector [α,β] if αy²≦yf(t,y)≦βy² ∀y ∈R, ∀t>0. In other words, a sector non-linearity would belong to sector [α,β] if it fell within the region bound by a first line having a slope of α and a second line having a slope of β. Because the baseband behavior of an Alexander phase detector exhibits this characteristic, Lyapunov redesign (as will be discussed in greater detail below) may be applied to Alexander-type PLLs.

The design methodology may begin by defining a candidate Lyapunov function that is parameterized by design parameters of an Alexander-type PLL. Then, a set of design constraints may be derived from said candidate Lyapunov function and a first derivative of said candidate Lyapunov function. From the design constraints, values for the design parameters of an Alexander-type PLL may be selected. Specifically, when the phase detector gain, the VCO gain, the filter coefficients, and/or the like are selected to satisfy the derived design constraints, the implemented Alexander-type PLL is ensured to be stable.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims. The features which are believed to be characteristic of the invention, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present invention.

### BRIEF DESCRIPTION OF THE DRAWINGS

For a more complete understanding of the present invention, reference is now made to the following descriptions taken in conjunction with the accompanying drawings, in which:

FIG. 1 depicts a mathematical model of a digital phase locked loop according to the prior art.

FIG. 2 depicts a flowchart of a design methodology for designing an Alexander-type PLL that is ensured to be stable for embodiments in accordance with the invention.

FIG. 3A depicts a mathematical representation of a third order PLL with two zeros that may be subjected to Lyapunov redesign to ensure PLL stability for embodiments in accordance with the invention.

FIG. 3B depicts another mathematical representation of a third order PLL with two zeros that is associated with no external inputs to be subjected to Lyapunov redesign for embodiments in accordance with the invention.

FIG. 3C depicts a PLL model arrangement to facilitate identification of the state variables of a third order PLL with two zeros for Lyapunov redesign to ensure PLL stability for embodiments in accordance with the invention.

FIG. 4A-4D depicts PLL models and blocks thereof to facilitate identification of the state variables of a fourth order PLL with two zeros for Lyapunov redesign to ensure PLL stability for embodiments in accordance with the invention.

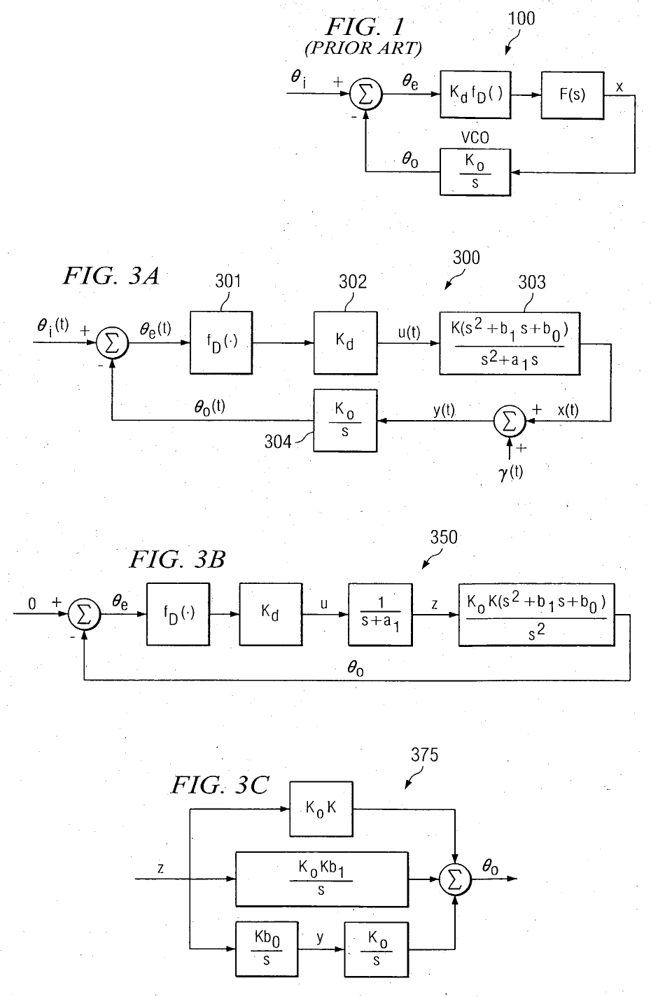

### DETAILED DESCRIPTION OF THE INVENTION

As previously noted, embodiments in accordance with the invention provide a design methodology that ensures a stable implementation of an Alexander-type PLL. The design methodology may begin by defining a candidate Lyapunov function that is parameterized by design parameters of an Alexander-type PLL. Then, a set of design constraints may be derived from said candidate Lyapunov function and a first derivative of said candidate Lyapunov function. From the design constraints, values for the design parameters of an Alexander-type PLL may be selected. Specifically, when the phase detector gain, the VCO gain, the filter coefficients, and/or the like are selected to satisfy the derived design constraints, the implemented Alexander-type PLL is ensured to be stable.

Before discussing embodiments in accordance with the invention, it is appropriate to provide a number of brief comments related to Lyapunov analysis of differential equations. The second method of Lyapunov is commonly utilized in stability analysis of nonlinear differential equations, because it does not require solution of the differential equations to demonstrate stability. The second method of Lyapunov is based on the generalized energy of a system characterized by a set of differential equations. If an energy-like function of the system state (i.e., a positive definite function of the state which is nonvanishing as long as the system state is nonzero) is found which is constantly decreasing, then the system is asymptotically stable. The energy-like function is referred to as the Lyapunov function (denoted herein as L(x)). Lyapunov analysis is quite intuitive in that system stability may be determined by demonstrating that the system continuously dissipates energy.

In general, it is useful to apply LaSalle's Theorem to demonstrate stability of a system characterized by a Lyapunov function. A system may be shown to be stable by demonstrating that:

L(x)≧0, L(x)=0→x=0

\dot{L}(x)≦0

L(x)→∞as ∥x∥→∞

\dot{L}(x)=0&\dot{x}=0→x=0

Additional details related to demonstrating system stability through LaSalle's Theorem may be found in “Control system analysis and design via the ‘Second Method’ of Lyapunov, Part 1: Continuous-Time Systems,” by R. E. Kalman and J. E. Bertram, Transactions of the ASME, 1959, which is incorporated herein by reference.

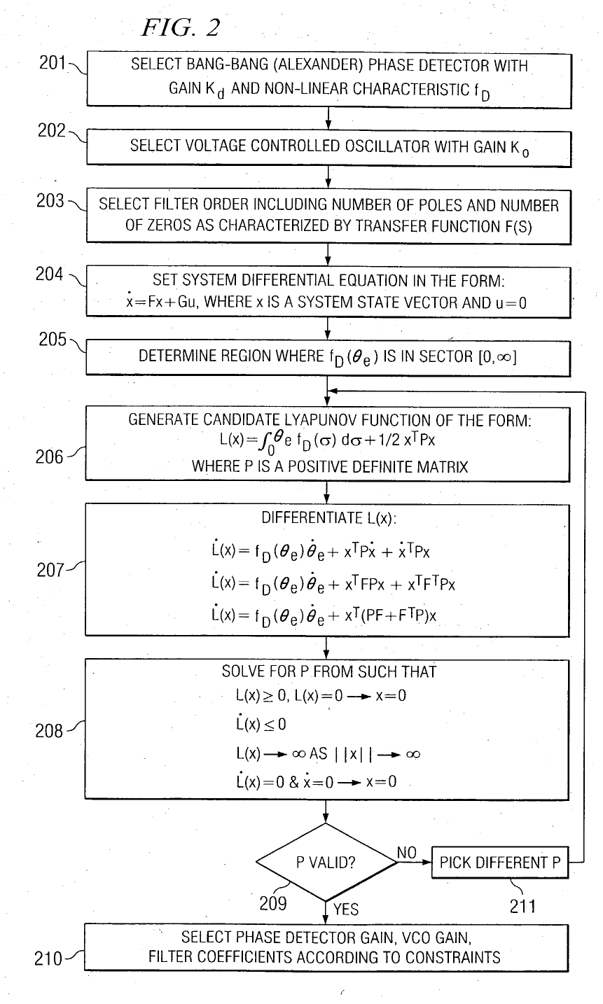

FIG. 2 depicts a flowchart of a design methodology for designing an Alexander-type PLL that is ensured to be stable according to embodiments in accordance with the invention. In step 201, a suitable Alexander (bang-bang) phase detector is selected with phase gain K_{d} and non-linear characteristic f_{D}. In step 202, a suitable voltage controlled oscillator is selected with gain Kₒ. In step 203, a filter order is selected including a number of poles and/or a number of zeros as characterized by transfer function F(s).

In system 204, the system differential equation representative of the Alexander-type PLL with the selected components is set by the form:

\dot{x}=Fx+Gu,

where x is the system state vector, \dot{x} is the first derivative of the system state vector, u is the system input (which is assumed to be zero).

In step 205, the region where f_{D}(θₑ) is in sector [0,∞] is determined. In step 206, from the region determined in step 205, the candidate Lyapunov function may be generated of the form:

$$L ( x ) = {\int }_{0}^{{θ}_{c}} {f}_{D} ( σ ) ⅆ σ + \frac{1}{2} {x}^{T} Px$$

where P is a symmetric, positive definite matrix that is parameterized by the design parameters of the Alexander-type PLL.

It shall be appreciated that this form of the Lyapunov function is convenient in that it is not necessary to take the derivative of the nonlinear phase detector characteristic. While it may be possible to determine the derivative over a limited range for some phase detectors, it may be inconvenient to do so. Furthermore, the derivative for the Alexander phase detector characteristic does not exist when θₑ=0.

Moreover, LaSalle's theorem can be used because the state vector, x, contains the energy storage elements of the system except the phase error. The phase error is taken into account by the integral term. The importance of the [0,∞] nonlinearity is that this assures that the integral is positive definite.

In step 207, the candidate Lyapunov function (L(x)) is differentiated resulting in:

\dot{L}(x)=f_{D}(θₑ)\dot{θ}ₑ+x^{T}P\dot{x}+\dot{x}^{T}Px

\dot{L}(x)=f_{D}(θₑ)\dot{θ}ₑ+x^{T}PFx+x^{T}F^{T}Px

\dot{L}(x)=f_{D}(θₑ)\dot{θ}ₑ+x^{T}(PF+F^{T}P)x

In step 208, an attempt is made to solve the positive definite matrix P so as to satisfy the following requirements:

L(x)≧0, L(x)=0→x=0

\dot{L}(x)≦0

L(x)→∞μas ∥x∥→∞

\dot{L}(x)=0&\dot{x}=0→x=0

In step 209, a logical comparison is made. If the matrix P is not valid (i.e., the requirements set forth in step 208 are not satisfied), the process flow proceeds to step 211 to select a different matrix P and then returns to step 206 where another candidate Lyapunov function is selected according to the different matrix P. If the matrix P is valid (i.e., the requirements set forth in step 208 are satisfied), the process flow proceeds to step 210. In step 210, values are selected for the design parameters according to the constraints resulting from the candidate Lyapunov function, its derivative, and the matrix P. Values may be selected for the phase detector gain, the VCO gain, the filter coefficients, and/or the like. By selecting the design parameters in this manner, the implementation of the resulting Alexander-type PLL is ensured to be stable.

To illustrate embodiments in accordance with the invention, reference is made to FIGS. 3A-3C. FIG. 3A depicts mathematical model 300 of a third order PLL with two zeros. Block 301 represents the non-linearity of the Alexander phase detector and block 302 represents the phase detector gain. Block 303 represents the transfer function of the loop filter. Block 304 represents an integrator with gain Kₒ corresponding to the VCO. Stability analysis is performed upon the homogenous case where there is no external input to the loop. Accordingly, model 350 of FIG. 3B may be employed. To facilitate the identification of the respective state variables of the loop, reference is made to block 375 of FIG. 3C. The state differential equations corresponding to model 350 and block 375 are:

\dot{z}=K_{d}f_{D}(θₑ)−a₁z

\dot{y}=Kb₀z

\dot{θ}ₑ=−KₒKK_{d}f_{D}(θₑ)−KₒK(b₁−a₁)z−Kₒy

The candidate Lyapunov function is given by:

$$L ( {θ}_{e} , y , z ) = {\int }_{0}^{{θ}_{c}} {f}_{D} ( σ ) ⅆ σ + \frac{1}{2} [ zy ] P [ \begin{matrix}z \\ y\end{matrix} ] ,$$

where P is a symmetric, positive definite 2×2 matrix.

In order to invoke LaSalle's Theorem, the parameterization of the matrix P must cause L(θₑ,y,z)≧0 with L(θₑ,y,z)=0 [symbol] θₑ=y=z=0, L(θₑ,y,z)=∞ when ∥y,z∥→∞ and \dot{L}(θₑ,y,z)≦0. Assuming −π<θₑ<π, these two conditions may be satisfied by selecting:

$$P = [ \begin{matrix}{K}_{o} K ( {b}_{1} - {a}_{1} ) / {K}_{d} & {K}_{o} / {K}_{d} \\ {K}_{o} / {K}_{d} & {K}_{o} {a}_{1} / ( {K}_{d} K {b}_{o} )\end{matrix} ]$$

KₒKK_{d}>0 [symbol] KₒK/K_{d}>0, K_{d}≠0

b₁>a₁(b₁, a₁ same sign)

b₀−(b₁−a₁)a₁<0

It is also convenient (but not necessary) to select both b₀ and a₁>0 since this corresponds to a stable loop filter. Also, it is convenient to select Kₒ, K, and K_{d}>0, leaving:

\dot{L}(θₑ,y,z)=−f_{D}(θₑ)²[KₒKK_{d}]+z²[(KₒK/K_{d})(b₀−(b₁−a₁)a₁)]≦0

Also, as ∥y,z∥→∞, L(θₑ,y,z)→∞. The only place that \dot{L}(θₑ,y,z), \dot{z}, \dot{y}, and θₑ can vanish is z=y=θₑ=0. Accordingly, the stability of the third order PLL is ensured to be stable when the loop parameters are selected as above in accordance with LaSalle's Theorem.

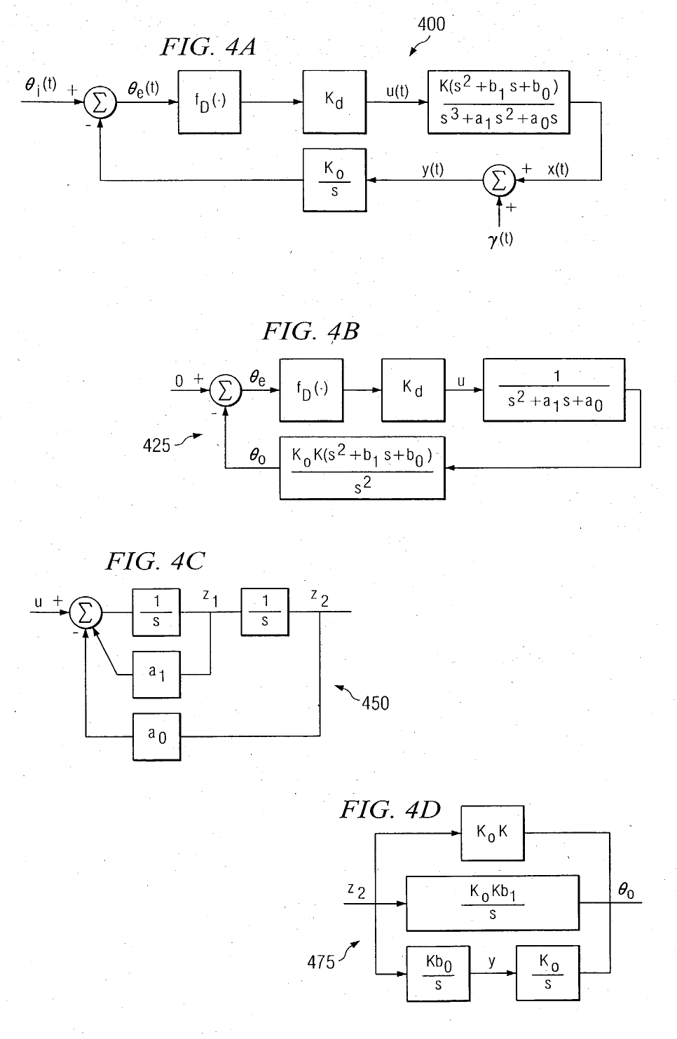

Lyapunov redesign may be applied to fourth order (or higher) Alexander-type PLLs in embodiments in accordance with the invention. FIG. 4A depicts fourth order PLL model 400 that has two zeros. PLL model 400 is analyzed according to the homogenous case where no input is applied to the system thereby resulting in PLL model 425 of FIG. 4B . To facilitate identification of the state variables (z₁, z₂, y), reference is made to block 450 of FIG. 4C and block 475 of FIG. 4D. The state differential equations corresponding to model 425 and blocks 450 and 475 are:

\dot{z}₁=K_{d}f_{D}(θₑ)−a₁z₁−a₀z₂

\dot{z}₂=z₁

\dot{y}=Kb₀z₂

\dot{θ}ₑ=−KₒKz₁−KₒKb₁z₂−Kₒy

The candidate Lyapunov function and its derivative are given by:

$$L ( {z}_{1} , {z}_{2} , y ) == {\int }_{0}^{{θ}_{c}} {f}_{D} ( σ ) ⅆ σ + \frac{1}{2} [ {z}_{1} {z}_{2} y ] P [ \begin{matrix}{z}_{1} \\ {z}_{2} \\ y\end{matrix} ]$$

$${L}^{•} ( {z}_{1} , {z}_{2} , y ) == {\int }_{0}^{{θ}_{c}} {f}_{D} ( σ ) ⅆ σ + [ {z}_{1} {z}_{2} y ] P [ \begin{matrix}• \\ {z}_{1} \\ • \\ {{z}_{2}}_{•} \\ y\end{matrix} ]$$

As previously noted, P is a symmetric, positive definite matrix. For the fourth order case, a diagonal P does not generate cancellation of terms. Accordingly, P is represented as follows:

$$[ \begin{matrix}p11 & p12 & p13 \\ p12 & p22 & p23 \\ p13 & p23 & p33\end{matrix} ]$$

Applying the matrix representation to the first derivative of the candidate Lyapunov function and substituting for the first derivatives of the state variables gives:

$${L}^{•} ( {z}_{1} , {z}_{2} , y ) = {f}_{D} ( {θ}_{e} ) [ - {K}_{0} {Kz}_{1} - {K}_{0} {Kb}_{1} {z}_{2} - {K}_{0} y + {z}_{1} {K}_{d} {p}_{11} + {z}_{2} {K}_{d} {p}_{12} + \\ {yK}_{d} {p}_{13} ] + {z}_{1}^{2} [ {p}_{12} - {a}_{1} {p}_{11} ] + {z}_{2}^{2} [ {Kb}_{0} {p}_{23} - {a}_{0} {p}_{12} ] + \\ {z}_{1} {z}_{2} [ {p}_{22} + {Kb}_{0} {p}_{13} - {a}_{1} {p}_{12} - {a}_{0} {p}_{11} ] + {z}_{1} y [ {p}_{23} - {a}_{1} {p}_{13} ] + {z}_{2} y [ {Kb}_{0} {p}_{33} - {a}_{0} {p}_{13} ]$$

To obtain the design parameters constraints by satisfying LaSalle's Theorem, it is convenient to select the matrix terms of P to simplify the first derivative of the candidate Lyapunov function. Specifically, it is convenient to select the matrix terms of P: (i) to cause the bracketed term multiplying f_{D}( θₑ) to equal zero; (ii) to cause the bracketed terms that respectively multiply z₁z₂, z₁y, and z₂y to equal zero; and (iii) to cause the bracketed terms that respectively multiply z₁² and z₂² to be less than zero.

By selecting the matrix terms of P in this manner, the matrix terms are: p₁₁=KₒK/K_{d}; p₁₂=KₒKb₁/K_{d}; p₁₃=Kₒ/K_{d}; p₂₂=KₒK(a₁b₁+a₀−b₀)/K_{d}; p₂₃=a₁p₁₃=a₁Kₒ/K_{d}; and p₃₃=a₀p₁₃/Kb₀=a₀Kₒ/(Kb₀K_{d}).

From these selections, the following set of design constraints for a fourth order PLL with two zeros may be derived:

KₒK/K_{d}>0

KₒK/(K_{d}b₀)>0

b₁<a₁

b₀a₁<b₁a₀

a₀b₁(a₁−b₁)+a₁b₀(b₁−a₁)+(a₀−b₀)²>0

Selection of the matrix terms of P and the design parameters in the manner discussed above results in LaSalle's Theorem being satisfied and thereby ensures that a PLL implemented according to these constraints will be stable. It is noted that a different set of design constraints may be obtained if KₒK/K_{d}<0 and/or the like.

The manipulations necessary to derive the parameter constraints may be simplified through appropriate use of symbolic manipulation software such as Mathematica from Wolfram Research or Maple from Maplesoft.

Thus, embodiments in accordance with the invention provide a design methodology that is substantially improved over known design methodologies for Alexander-type PLLs. Known design methodologies provide mere approximate analysis techniques for first and second order Alexander-type PLLs and cannot demonstrate loop stability. Specifically, known methodologies provide heuristic simplifications that provide some intuition for first and second order Alexander-type PLLs. However, known design methodologies provide no insight for higher order (i.e., of order three or greater) Alexander-type PLLs and cannot demonstrate loop stability for higher order Alexander-type PLLs. In other words, known methodologies provide no guidance for implementing a stable higher order Alexander-type PLL. In contrast, embodiments in accordance with the invention enable a low order or a high order Alexander-type PLL to be implemented that is ensured to be stable. Specifically, by selecting design parameters within the constraints as defined by a suitable candidate Lyapunov function, embodiments in accordance with the invention ensure that the resulting Alexander-type PLL is stable.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

1. A method for designing an Alexander-type phase lock loop (PLL), comprising:
defining a candidate Lyapunov function that is parameterized by design parameters of said Alexander-type PLL;
deriving a set of design constraints from said candidate Lyapunov function and a first derivative of said candidate Lyapunov function; and
selecting values for design parameters of said Alexander-type PLL such that said values satisfy said design constraints.

2. The method of claim 1 wherein said deriving said set of design constraints includes determining design constraints such that said first derivative of said candidate Lyapunov function is less than or equal to zero.

3. The method of claim 1 wherein said deriving said set of design constraints includes determining design constraints such that said first derivative of said candidate Lyapunov function and first derivative of system state equals zero when each state variable of said candidate Lyapunov function equals zero.

4. The method of claim 1 wherein said deriving said set of design constraints includes determining design constraints such that each state variable of said candidate Lyapunov function equals zero when said first derivative of said candidate Lyapunov function and first derivative of system state equals zero.

5. The method of claim 1 wherein said deriving said set of design constraints includes determining design constraints such that said candidate Lyapunov function equals zero when each state variable of said candidate Lyapunov function equals zero.

6. The method of claim 1 wherein said deriving said set of design constraints includes determining design constraints such that said candidate Lyapunov function is a positive definite.

7. The method of claim 1 wherein said deriving said set of design constraints includes determining design constraints such that said candidate Lyapunov function approaches infinity when a norm of state variables of said candidate Lyapunov function approaches infinity.

8. The method of claim 1 wherein said Alexander-type PLL has an order greater than two.

9. The method of claim 1 wherein said selecting values for design parameters includes selecting a phase detector gain.

10. The method of claim 1 wherein said selecting values for design parameters includes selecting a voltage controlled oscillator (VCO) gain.

11. The method of claim 1 wherein said selecting values for design parameters includes selecting filter coefficients.

12. A method for designing a phase lock loop (PLL) that utilizes a phase detector that generates a first uniform signal when a loop signal is late relative to a reference signal and a second uniform signal when the loop signal is early relative to the reference signal, the method comprising:
defining a positive definite candidate Lyapunov function that is parameterized by design parameters of said PLL;
deriving a set of design constraints from said candidate Lyapunov function and a first derivative of said candidate Lyapunov function such that said first derivative is less or equal to zero; and
selecting values for design parameters of said PLL such that said values satisfy said design constraints.

13. The method of claim 12 wherein said deriving said set of design constraints includes determining design constraints such that said first derivative of said candidate Lyapunov function and first derivative of system state equals zero when each state variable of said candidate Lyapunov function equals zero.

14. The method of claim 12 wherein said deriving said set of design constraints includes determining design constraints such that each state variable of said candidate Lyapunov function equals zero when said first derivative of said candidate Lyapunov function and first derivative of system state equals zero.

15. The method of claim 12 wherein said deriving said set of design constraints includes determining design constraints such that said candidate Lyapunov function equals zero when each state variable of said candidate Lyapunov function equals zero.

16. The method of claim 12 wherein said deriving said set of design constraints includes determining design constraints such that said candidate Lyapunov function approaches infinity when a norm of state variables of said candidate Lyapunov function approaches infinity.

17. The method of claim 12 wherein said PLL has an order greater than two.

18. The method of claim 12 wherein said selecting values for design parameters includes selecting a phase detector gain.

19. The method of claim 12 wherein said selecting values for design parameters includes selecting a voltage controlled oscillator (VCO) gain.

20. The method of claim 13 wherein said selecting values for design parameters includes selecting filter coefficients.
